(19) United States
(12) Patent Application Publication
(10) Pub. No.: US 2012/0164438 A1
(43) Pub. Date: Jun. 28, 2012

(54) PROCESS FOR SURFACE TREATING ALUMINUM OR ALUMINUM ALLOY AND ARTICLE MADE WITH SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); DUN MAO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/191,586

(22) Filed: Jul. 27, 2011

(30) Foreign Application Priority Data
Dec. 28, 2010 (CN) 201010609221.0

(51) Int. Cl. B32B 15/04; B05D 7/00; B05D 3/02; C23C 14/34; B05D 3/10; C23C 16/22; C23C 16/44; C23C 14/00; B32B 18/00; B05D 3/04

(52) U.S. Cl. 428/336; 428/447; 427/248.1; 427/523; 204/192.1

(57) ABSTRACT

A process for treating the surface of aluminum or aluminum alloy comprises providing a substrate made of aluminum or aluminum alloy. Then a silane-based hybrid film doped with cerous salt is formed on the substrate by sol-gel process, and a ceramic coating comprising refractory compound is formed on the silane-based hybrid film by physical vapor deposition.

### CROSS-REFERENCE TO RELATED APPLICATIONS

This application is related to co-pending U.S. patent applications (Attorney Docket No. US35145, and US36042, each entitled “PROCESS FOR SURFACE TREATING ALUMINUM OR ALUMINUM ALLOY AND ARTICLE MADE WITH SAME”, each invented by Chang et al. These applications have the same assignee as the present application. The above-identified applications are incorporated herein by reference.

### BACKGROUND

1. Technical Field

The disclosure generally relates to a process for surface treating aluminum or aluminum alloy, and articles made of aluminum or aluminum alloy treated by the process.

2. Description of Related Art

Aluminum and aluminum alloy are becoming widely used in manufacturing components (such as housings) of electronic devices and cars because of their many desirable properties such as light weight and quick heat dissipation. However, aluminum or aluminum alloy have relatively low erosion resistance and abrasion resistance. One method for enhancing the erosion resistance of aluminum or aluminum alloy is to form ceramic coatings on its surface. However, magnesium alloy, typically casting magnesium alloy usually has recesses on its surface. Portions of the ceramic coatings corresponding to these recesses are usually thinner than other portions, causing these portions to be easily corroded (also known as pitting corrosion).

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary process for surface treating aluminum or aluminum alloy and articles made with same. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary article treated by the present process.

FIG. 2 is a cross-sectional view of another exemplary article treated by the present process.

FIG. 3 is a block diagram of a process for the surface treatment of aluminum or aluminum alloy according to an exemplary embodiment.

### DETAILED DESCRIPTION

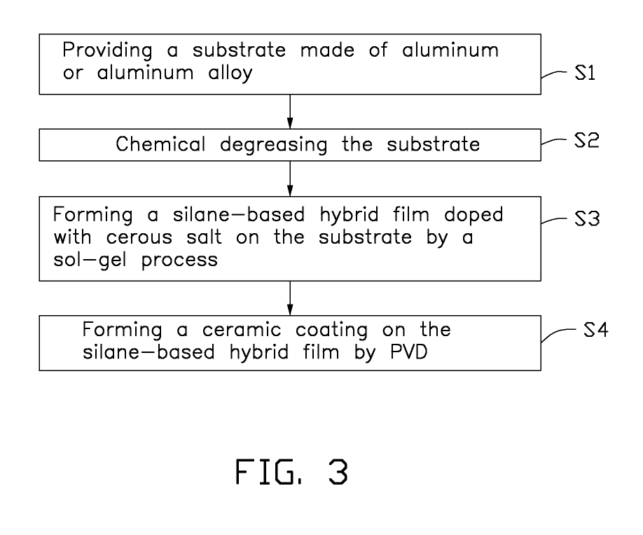

Referring to FIG. 3, an exemplary process for the surface treatment of aluminum or aluminum alloy may include steps S1 to S4.

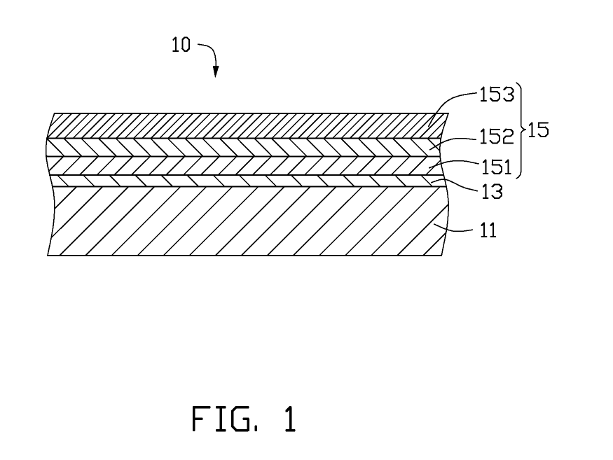

In step S1, referring to FIG. 1, a substrate 11 is provided. The substrate 11 is made of aluminum or aluminum alloy.

In step S2, the substrate 11 is pretreated. During this step, the substrate 11 may be chemically degreased with an aqueous solution, to remove impurities such as grease or dirt from the substrate 11. The aqueous solution contains about 25 g/L-30 g/L sodium carbonate (Na₂CO₃), about 20 g/L-25 g/L trisodium phosphate dodecahydrate (Na₃PO₄.12H₂O), and an emulsifier. The emulsifier may be a trade name emulsifier OP-10 (a condensation product of alkylphenol and ethylene oxide) at a concentration of about 1 g/L-3 g/L. The substrate 11 is immersed in the aqueous solution, which is maintained at a temperature of about 60° C.-80° C., for about 30 s-60 s. Then, the substrate 11 is rinsed.

In step S3, when the pretreatment is finished, a silane-based hybrid film 13 doped with cerous salt is formed on the substrate 11 by a sol-gel process. The sol-gel process may be implemented as follows. Tetraethyl orthosilicate (TEOS), 3-glycidoxypropyl-trimethoxysilane (GPTMS), ethanol, cerium nitrate, and water are mixed at a weight ratio of about (10-20):(30-40):(10-20):(2-5):(15-30), to produce a first mixture, which is stirred to be made homogeneous. Then the pH of the first mixture is adjusted to about 3.8-4.2 using acetic acid and sodium acetate. The first mixture is sealed in a container and retained in a constant temperature water bath, which is at a temperature of about 30° C.-60° C., for about 8 hours (h) to 12 h, thereby the first mixture hydrolyzes to achieve a silane-based hybrid sol. Ethylenediaminetetraacetic acid (EDTA) may be added into the silane-based hybrid sol to form a second mixture, which is stirred to be made homogeneous to achieve a film-forming solution. The weight of the EDTA is about 2% to about 4% of the weight of the silane-based hybrid sol. The EDTA is used as a scale inhibitor. The film-forming solution is coated on the substrate 11 by immersing or by brushing, and then air dried to form a stable gel layer. The gel layer is next solidified at a solidifying temperature between 120° C.-150° C., forming a dense silane-based hybrid film 13 doped with cerous salt on the substrate 11. In an exemplary embodiment, the ratio of the TEOS, GPTMS, ethanol, cerium nitrate, and water is 10:20: 10:2:15. The hydrolysis takes about 10 h. The hydrolysis temperature is about 40° C. The solidifying temperature is about 130° C. The thickness of the silane-based hybrid film 13 may be about 0.1 micrometer (μm) to about 0.4 μm.

In step S4, a ceramic coating 15 is formed on the silane-based hybrid film 13 by physical vapor deposition (PVD), such as vacuum sputtering or arc ion plating. The ceramic coating 15 may be a single layer or multilayer refractory compound. The refractory compound can be selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt.

In one exemplary embodiment, the ceramic coating 15 orderly includes a AlON layer 151 coated on the silane-based hybrid film 13, a AlO layer 152 on the AlON layer 151, and a AlN layer 153 on the AlO layer 152. The AlON layer 151 is an aluminum-oxygen-nitrogen compound layer. The AlO layer 152 is an aluminum-oxygen compound layer. The AlN layer 153 is an aluminum-nitrogen compound layer.

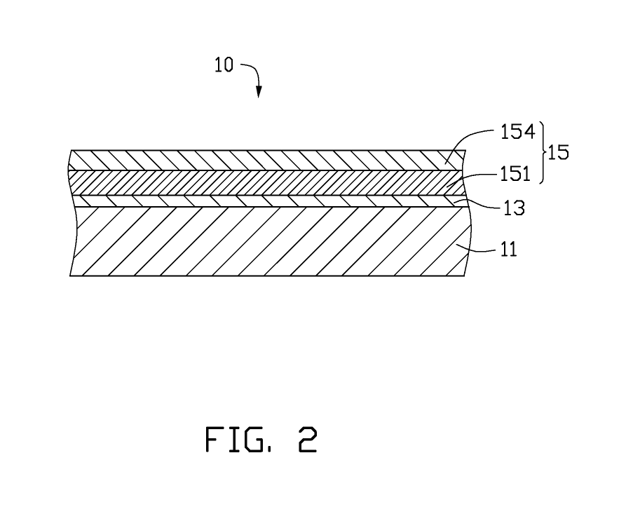

Referring to FIG. 2, in another embodiment, the ceramic coating 15 includes a AlON layer 151 formed on the silane-based hybrid film 13 and a CrON layer 154 directly formed on the AlON layer 151. The CrON layer 154 is a chromium-oxygen-nitrogen compound layer.

The silane-based hybrid film 13 provides a smooth surface on the substrate 11, and by such means the ceramic coating 15 formed on silane-based hybrid film 13 has a substantially even thickness, reducing the susceptibility to pit corrosion. In addition, the silane-based hybrid film 13 firmly bonding to the substrate 11 has a good chemical stability and high density, having a good erosion resistance. Having a high resistance to abrasion, the ceramic coating 15 protects the silane-based hybrid film 13 from mechanical abrasion.

FIG. 1 shows a cross-section of an exemplary article 10 made of aluminum or aluminum alloy and processed by the surface treatment process described above. The article 10 may be a housing for an electronic device, such as a mobile phone. The article 10 includes the substrate 11 made of aluminum or aluminum alloy, the silane-based hybrid film 13 formed on the substrate 11, and the ceramic coating 15 formed on the silane-based hybrid film 13 by PVD.

The silane-based hybrid film 13 is formed by a sol-gel process using a silane-based hybrid sol, which is hydrolyzed from a mixture containing TEOS, GPTMS, ethanol, cerium nitrate, and water, as described above. The silane-based hybrid film 13 substantially comprises Si, O, C, and H. The atomic ratio of Si, O, C, and H is about (0.1-2):(2-3):(2-4):(2-8). The thickness of the silane-based hybrid film 13 may be about 0.1 micrometer (μm) to about 0.4 μm.

The ceramic coating 15 may be a single layer or multilayer refractory compound. The refractory compound can be selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt.

In one exemplary embodiment, the ceramic coating 15 orderly includes a AlON layer 151 coated on the silane-based hybrid film 13, a AlO layer 152, and a AlN layer 153. The AlON layer 151 is an aluminum-oxygen-nitrogen compound layer. The AlO layer 152 is an aluminum-oxygen compound layer. The AlN layer 153 is an aluminum-nitrogen compound layer.

Referring to FIG. 2, in another embodiment, the ceramic coating 15 includes a AlON layer 151 formed on the silane-based hybrid film 13 and a CrON layer 154 directly formed on the AlON layer 151. The CrON layer 154 is a chromium-oxygen-nitrogen compound layer.

A neutral salt spray test was applied to samples created by the present process. The test conditions included 5% NaCl (similar to salt-fog chloride levels), that was neutral at 35° C. to simulate condensing gases with moisture and salt. The test was an accelerated corrosion test for assessing coating performance. Erosion began to be observed after about 72 hours, indicating that the samples resulting from the present process have a good erosion resistance.

It is to be understood, however, that even through numerous characteristics and advantages of the exemplary disclosure have been set forth in the foregoing description, together with details of the system and functions of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A process for surface treating aluminum or aluminum alloy, the process comprising the following steps of:
providing a substrate made of aluminum or aluminum alloy;
forming a silane-based hybrid film doped with cerous salt on the substrate by a sol-gel process; and
forming a ceramic coating comprising a refractory compound on the silane-based hybrid film by physical vapor deposition.

2. The process as claimed in claim 1, wherein the sol-gel process comprises the following steps:
mixing tetraethyl orthosilicate, 3-glycidoxypropyl-trimethoxysilane, ethanol, cerium nitrate, and water at a weight ratio of about (10-20):(30-40):(10-20):(2-5): (15-30), to produce a first mixture;
adjusting the pH of the first mixture to about 3.8-4.2 using acetic acid and sodium acetate; hydrolyzing the first mixture at a temperature of about 30° C.-60° C. for about 8 h to 12 h, to produce a silane-based hybrid sol;
coating the silane-based hybrid sol on the substrate and air drying to form a stable gel layer; and solidifying the gel layer at a solidifying temperature between 120° C.-150° C., to form the silane-based hybrid film on the substrate.

3. The process as claimed in claim 2, wherein the sol-gel process further comprises a step of adding ethylenediaminetetraacetic acid into the silane-based hybrid sol, before coating the silane-based hybrid sol on the substrate.

4. The process as claimed in claim 2, wherein the weight ratio of the tetraethyl orthosilicate, 3-glycidoxypropyl-trimethoxysilane, ethanol, cerium nitrate, and water is about 10:20:10:2:15.

5. The process as claimed in claim 2, wherein the hydrolyzing temperature is about 40° C.

6. The process as claimed in claim 2, wherein the hydrolyzing takes for about 10 hours.

7. The process as claimed in claim 2, wherein the solidifying temperature is about 130° C.

8. The process as claimed in claim 1, wherein the silane-based hybrid film substantially comprises Si, O, C, and H, the atomic ratio of Si, O, C, and H is about (0.1-2):(2-3):(2-4):(2-8).

9. The process as claimed in claim 1, wherein the ceramic coating orderly includes a AlON layer coated on the silane-based hybrid film, a AlO layer on the AlON layer, and a AlN layer on the AlO layer; the AlON layer is an aluminum-oxygen-nitrogen compound layer; the AlO layer is an aluminum-oxygen compound layer; the AlN layer is an aluminum-nitrogen compound layer.

10. The process as claimed in claim 1, wherein the ceramic coating includes a AlON layer formed on the silane-based hybrid film and a CrON layer formed on the AlON layer; the AlON layer is an aluminum-oxygen-nitrogen compound layer; the CrON layer is a chromium-oxygen-nitrogen compound layer.

11. The process as claimed in claim 1, wherein the physical vapor deposition uses a vacuum sputtering method or an arc ion plating method.

12. The process as claimed in claim 1, further comprising chemically degreasing the substrate with an aqueous solution containing about 25 g/L-30 g/L Na₂CO₃, about 20 g/L-25 g/L Na₃PO₄.12H₂O, and an emulsifier.

13. An article, comprising:
a substrate made of aluminum or aluminum alloy;
a silane-based hybrid film doped with cerous salt formed on the substrate; and
a ceramic coating comprising a refractory compound formed on the silane-based hybrid film.

14. The article as claimed in claim 13, wherein the silane-based hybrid film substantially comprises Si, O, C, and H, the atomic ratio of Si, O, C, and H is about (0.1-2):(2-3):(2-4):(2-8).

15. The article as claimed in claim 13, wherein the thickness of the silane-based hybrid film is about 0.1 μm to about 0.4 μm.

16. The article as claimed in claim 13, wherein the ceramic coating orderly includes a AlON layer coated on the silane-based hybrid film, a AlO layer on the AlON layer, and a AlN layer on the AlO layer; the AlON layer is an aluminum-oxygen-nitrogen compound layer; the AlO layer is an aluminum-oxygen compound layer; the AlN layer is an aluminum-nitrogen compound layer.

17. The article as claimed in claim 13, wherein the ceramic coating includes a AlON layer formed on the silane-based hybrid film and a CrON layer formed on the AlON layer; the AlON layer is an aluminum-oxygen-nitrogen compound layer; the CrON layer is a chromium-oxygen-nitrogen compound layer.
